(19) United States
(12) Patent Application Publication
(10) Pub. No.: US 2023/0321752 A1
(43) Pub. Date: Oct. 12, 2023

(54) WORKPIECE SEPARATION DEVICE AND WORKPIECE SEPARATION METHOD

(71) Applicant: SHIN-ETSU ENGINEERING CO., LTD., Tokyo (JP)

(72) Inventors: Yoshikazu OHTANI, Gunma (JP); Kyouhei TOMIOKA, Gunma (JP)

(73) Assignee: SHIN-ETSU ENGINEERING CO., LTD., Tokyo (JP)

(21) Appl. No.: 18/025,443

(22) PCT Filed: Jan. 21, 2021
(86) PCT No.: PCT/JP2021/002040

§ 371 Date: Mar. 9, 2023

(51) Int. Cl. B23K 26/062; H01L 21/683; B23K 26/03

(52) U.S. Cl. CPC B23K 26/062; H01L 21/6835; B23K 26/032; B23K 2101/40

(57) ABSTRACT

A workpiece separating device for irradiating a laminated body including a workpiece having a circuit substrate bonded with a supporting body via a separating layer with a light, thereby denaturing the separating layer, and peeling the supporting body from the workpiece, the workpiece separating device comprising: a holding member for detachably holding any one of the workpiece side or the supporting body of the laminated body; a light irradiation part for irradiating the light toward the separating layer through the other of the supporting body or the workpiece side of the laminated body held by the holding member; an isolation member for, with respect to any one of the workpiece side or the supporting body of the laminated body, isolating and moving the other in the thickness direction; and a controlling part for operation controlling the light irradiation part and the isolation member.

### TECHNICAL FIELD

The present invention relates to a workpiece separating device to be used for peeling a workpiece temporarily fixed and supported to a supporting body in the manufacturing step of a workpiece to be a product such as WLP (wafer level packaging), PLP (panel level packaging), or a processing of a semiconductor wafer with a relatively smaller thickness, and a workpiece separating method using the workpiece separating device.

### BACKGROUND ART

Conventionally, as this kind of workpiece separating device and workpiece separating method, there is proposed a system capable of sufficiently standing the process of back surface grinding, TSV, or back surface electrode formation by bonding a semiconductor substrate (thin type wafer) to a supporting body of silicon, glass, or the like via a temporary adhesion material layer (see, e.g., PTL 1).

The temporary adhesion material layer includes a first temporary adhesion layer formed of a thermoplastic resin stacked on the surface of a semiconductor substrate (wafer with a circuit), a second temporary adhesion layer formed of a thermosetting resin stacked on the first temporary adhesion layer, and a third temporary adhesion layer formed of the component of the separating layer stacked between the supporting body and the second temporary adhesion layer. With the stacking method of the temporary adhesion material layer, the material of each temporary adhesion layer is dissolved in solvent, and stacked using a spin coat method or the like. With the stacking method of the second temporary adhesion layer, a thermosetting resin layer is stacked on the supporting body on which the separating layer is stacked.

As the separating method of the supporting body, mention may be made of a light laser peeling system of changing the adhesive strength by irradiation with a light or a laser, and thereby enabling the separation thereof. For the separation of the supporting body by the light laser peeling system, a light or a laser is irradiated from the supporting body side, thereby causing a change of properties in the separating layer, and thereby reducing the adhesive strength of the supporting body and the separating layer, or the like. As a result, the supporting body is separated without inflicting a damage to a semiconductor substrate (wafer with a circuit).

### CITATION LIST

### Patent Literature

[PTL 1] Japanese Patent Application Publication No. 2017-098474

### SUMMARY OF INVENTION

### Technical Problem

Incidentally, air bubbles may be generated when the component of the separating layer is stacked along the supporting body. The air bubbles mixed in the component of the separating layer become voids (cavities), and are left in the separating layer.

However, in PTL 1, after stacking of the component of the separating layer along the supporting body, the thermosetting resin of the second temporary adhesion layer is stacked along the separating layer. For this reason, the thermosetting resin flows into the voids of the separating layer. The thermosetting resin flowed into the voids of the separating layer is solidified while being in contact with the surface of the supporting body, resulting in a partial adhesion state.

In this case, even when irradiation with a light or a laser changes the adhesive strength of the separating layer, the partial adhesion state remains. For this reason, the supporting body cannot be separated from the semiconductor substrate (the wafer with a circuit).

When the supporting body is forcedly separated by this, undesirably, the device formed in the circuit mounted on the semiconductor substrate may be damaged, or the semiconductor substrate may be cracked, or at worst, the semiconductor substrate may be broken.

### Solution to Problem

In order to solve such a problem a workpiece separating device in accordance with the present invention is a workpiece separating device for irradiating a laminated body including a workpiece having a circuit substrate bonded with a supporting body via a separating layer with a light, thereby denaturing the separating layer, and peeling the supporting body from the workpiece. The device is characterized by including: a holding member for detachably holding any one of the workpiece side or the supporting body of the laminated body; a light irradiation part for irradiating the light toward the separating layer through the other of the supporting body or the workpiece side of the laminated body held by the holding member; an isolation member for, with respect to any one of the workpiece side or the supporting body of the laminated body, isolating and moving the other in the thickness direction; and a controlling part for operation controlling the light irradiation part and the isolation member. The device is characterized in that the laminated body has the separating layer stacked along a surface of the supporting body, and a solidification layer stacked along the separating layer, and in that the controlling part performs control such that whole irradiation in which the light is irradiated over the entire surface of the separating layer by the light irradiation part and selective irradiation in which the light is partially irradiated to only an adhesion region between the surface of the supporting body and the solidification layer are performed.

Further, in order to solve such a problem, a workpiece separating method in accordance with the present invention is a workpiece separating method for, with respect to a laminated body including a workpiece having a circuit substrate stacked with a supporting body via a separating layer, peeling the supporting body from the workpiece due to denaturing of the separating layer accompanying irradiation with a light. The method is characterized by including: a holding process of detachably holding any one of the workpiece side or the supporting body of the laminated body at a holding member; and a light irradiation process of irradiating the light from the light irradiation part toward the separating layer through the other of the supporting body or the workpiece side of the laminated body held by the holding member. The method is characterized in that the laminated body has the separating layer stacked along a surface of the supporting body and a solidification layer stacked along the separating layer, and in that at the light irradiation process, whole irradiation in which the light is irradiated over the entire surface of the separating layer by the light irradiation part and selective irradiation in which the light is partially irradiated only to an adhesion region of the surface of the supporting body and the solidification layer are performed.

### BRIEF DESCRIPTION OF DRAWINGS

FIG. 1 is an explanatory view showing a workpiece separating device and the molding step in a workpiece separating method in accordance with an embodiment (a first embodiment) of the present invention, where (a) is a longitudinal front view at the time of coating of a separating layer, (b) is a longitudinal front view at the time of mounting of workpieces, and (c) is a longitudinal front view at the time of bonding.

FIG. 2 is a plan view along line (2)-(2) of FIG. 1 at (c).

FIG. 3 is a longitudinal front view showing the workpiece separating device, and the separating step in a workpiece separating method in accordance with the embodiment (the first embodiment) of the present invention, where (a) is a longitudinal front view at the time of whole irradiation, (b) is a longitudinal front view at the time of selective irradiation, and (c) is a longitudinal front view at the time of isolation.

FIG. 4 is an explanatory view showing a workpiece separating device and the molding step in a workpiece separating method in accordance with an embodiment (a second embodiment) of the present invention, where (a) is a longitudinal front view at the time of coating of a separating layer, (b) is a longitudinal front view at the time of mounting of workpieces, and (c) is a longitudinal front view at the time of bonding.

FIG. 5 is a longitudinal front view showing the workpiece separating device, and the separating step in a workpiece separating method in accordance with the embodiment (the second embodiment) of the present invention, where (a) is a longitudinal front view at the time of whole irradiation, (b) is a longitudinal front view at the time of selective irradiation, and (c) is a longitudinal front view at the time of isolation.

### DESCRIPTION OF EMBODIMENTS

Below, embodiments of the present invention will be described in detail by reference to the accompanying drawings.

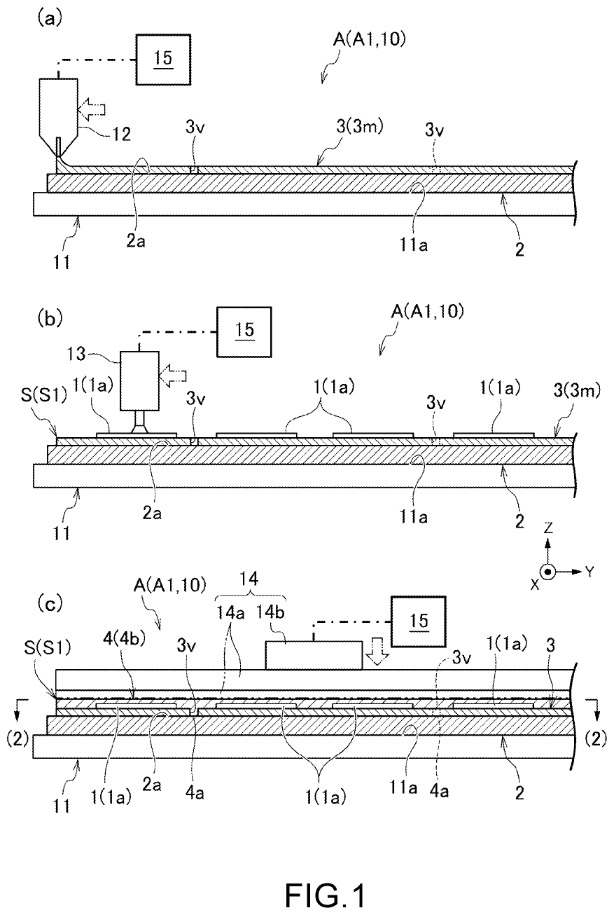

A workpiece separating device A and a workpiece separating method in accordance with an embodiment of the present invention are a device and a method whereby, as shown in FIGS. 1 to 5, a laminated body S including therein workpieces 1 including circuit substrates (not shown), and a supporting body 2 for holding the workpieces 1 in a flat state bonded via a separating layer 3 therebetween is irradiated with a light L, which causes the separating layer 3 to be denatured (to be changed in properties) to a peelable state, for peeling the supporting body 2 from the workpieces 1. These are used for manufacturing of a semiconductor package, or the like such as WLP (wafer level packaging) or PLP (panel level packaging), or the processing of a semiconductor wafer with a very small thickness (which will be hereinafter referred to as a “very thin wafer”).

In particular, the workpiece separating device A in accordance with an embodiment of the present invention includes a molding device 10 by which the workpieces 1 and the supporting body 2 are bonded with each other with the separating layer 3 interposed therebetween, and a peeling device 20 for enabling peeling between the workpieces 1 and the supporting body 2 by denaturing (changing in properties) of the separating layer 3 due to irradiation with a light L.

Incidentally, as shown in FIGS. 1 to 5, the workpieces 1, the supporting body 2, and the laminated body S are normally placed so that the front surfaces or the back surfaces thereof are oriented vertically. Thickness direction of the workpieces 1, the supporting body 2, and the laminated body S will be hereinafter referred to as a “Z direction”. The two directions crossing with the thickness direction (Z direction) are referred to as XY directions”.

The workpieces 1 are device substrates formed of a material such as silicon in a thin sheet shape, and including transportable substrates, or the like including circuit substrates subjected to a semiconductor process such as a circuit forming treatment or a thinning treatment. The overall shape of the workpieces 1 are formed in panel shapes of rectangles (quadrilaterals with right-angled corners including rectangles and squares), circular wafer shapes, or the like.

Specific examples of the workpieces 1 may include semiconductor elements 1a such as semiconductor chips, or the similar ones.

The front surfaces of the workpieces 1 are subjected to processing such as a circuit forming treatment or a thinning treatment with the back surface thereof bonded with the supporting body 2 via the separating layer 3. After completion of the processing, the separating layer 3 is changed in properties, which enables peeling of the supporting body 2 from the workpieces 1.

The workpieces 1 also include substrates formed of rectangular or circular semiconductor elements thinned in thickness to, for example, 15 to 3,000 μm. In particular, in the case of a panel shape or a wafer shape with a thickness of the workpieces 1 as very thin as about several tens micrometers (which will be referred to as “very thin”), it is also possible to bond the entire surface of the workpieces 1 to a tape-shaped holding adhesive sheet such as a dicing tape or the like for supporting, and to bond the workpieces 1 to a tape-shaped holding adhesive sheet with the outer circumferential part thereof reinforced by a holding frame in a quadrilateral frame shape or a circular frame shape (ring shape) such as a dicing frame or the like for supporting.

Incidentally, when a light L described later is irradiated toward the separating layer 3 through the workpiece 1 side, the workpieces 1 can be formed of a transparent or translucent material capable of transmitting the light L therethrough.

The supporting body 2 is the one referred to as a carrier substrate, a support substrate, or the like for holding the workpieces 1 in a flat state in the thinning process, various treatment processes, the transport process, and the like of the workpieces 1, and thereby allowing the workpieces 1 to have a necessary strength and preventing the breakage, the deformation, or the like of the workpieces 1. For this reason, the supporting body 2 is a hard rigid material, and is formed in a rectangular or circular shape with a size corresponding to that of the workpieces 1 or the like.

The supporting body 2 is preferably formed of a transparent or translucent rigid material such as glass or a synthetic resin capable of transmitting a light L described later therethrough in a flat sheet shape.

As a specific example of the supporting body 2, a rectangular sheet or a circular sheet made of a glass sheet, a ceramic sheet, an acrylic resin, or the like with a thickness of, for example, 300 to 3,000 μm is used. In the case of the example shown, a transparent glass sheet for transmitting therethrough a laser light beam with a specific wavelength as the light L from the light irradiation part 22 is used.

The separating layer 3 is formed of a denature material 3m having an appropriate adhesive strength and to be denatured (changed in properties) in a manner capable of controlling the adhesive strength, and is formed in a lamination in such a manner as to be sandwiched between the workpieces 1 and the supporting body 2.

The denature material 3m is formed of a light reactive resin, or the like. As the method for controlling the adhesive strength of the denature material 3m, there is used the one for reducing the adhesive strength due to the absorption of the light L, or the like, and causing denaturing (change in properties) in a manner capable of peeling the workpieces 1 and the supporting body 2. As the lights L for changing the properties of the separating layer 3 and the denature material 3m, mention may be made of a laser light beam, a heat ray (infrared ray), and other light beams. Out of these, a laser light beam is preferably used because the light beam with a high energy density can be irradiated to the object. Further, for the denature material 3m, the one which can be cleaned and removed with ease after peeling the workpieces 1 and the supporting body 2 is preferably used.

With the lamination method of the separating layer 3, using a slit coat method, a spin coat method, or the like, the denature material 3m is coated along the surface 2a of the supporting body 2, followed by heating, sintering, or the like, resulting in solidification.

In the case where the denature material 3m has a sufficient adhesive property as with, for example, a polyimide resin as one example of the denature material 3m, as shown in FIGS. 1 to 3, only the denature material 3m bonds the workpieces 1 and the supporting body 2 detachably.

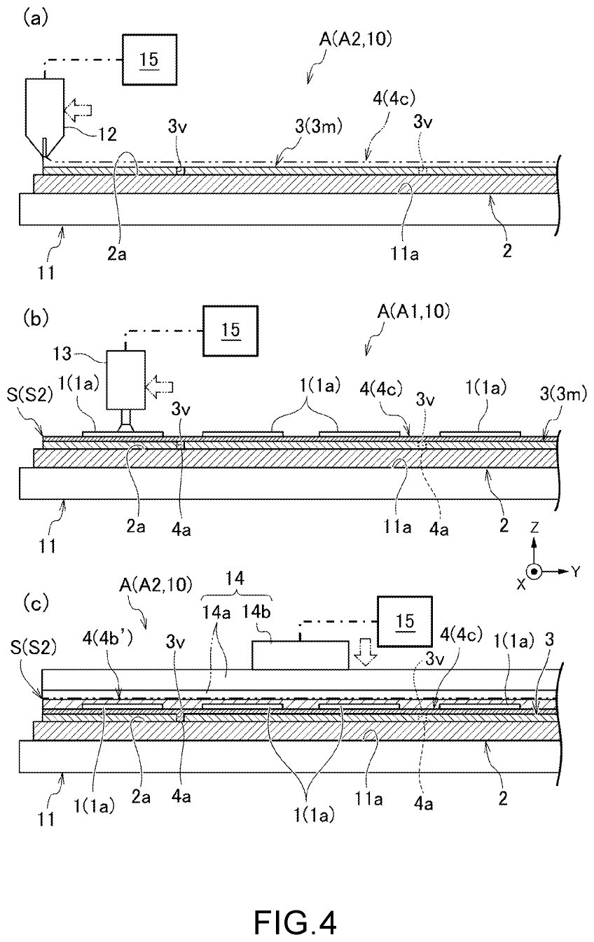

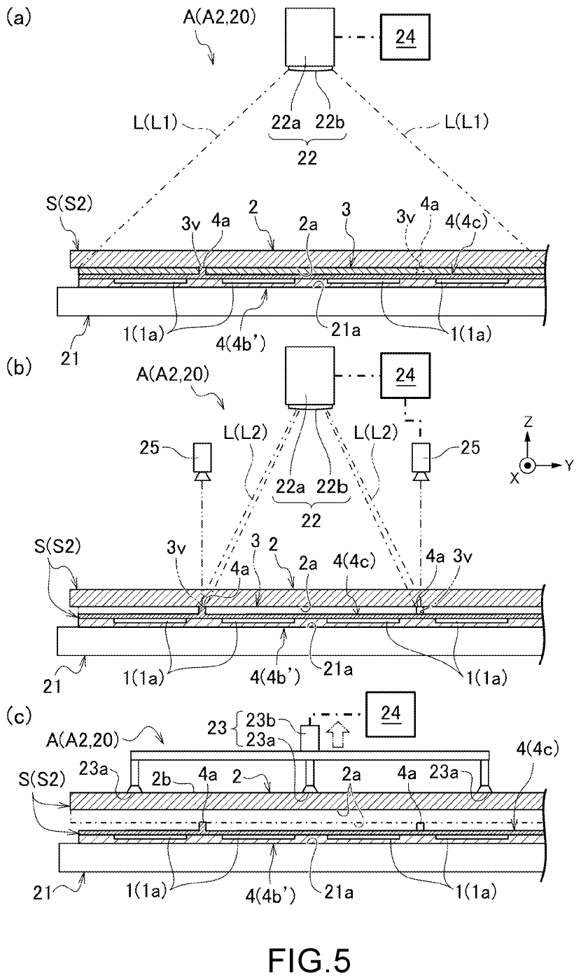

In the case where the denature material 3m does not have a necessary adhesive strength as another example of the separating layer 3, as shown in FIGS. 4 and 5, an adhesion layer 4c described later is disposed, so that the adhesion layer 4c bonds the workpieces 1, and the separating layer 3 and the supporting body 2 detachably.

With the lamination method of the adhesion layer 4c, using a slit coat method, a spin coat method, or the like, an adhesive is coated along the separating layer 3.

As the laminated body S, the one thinned in thickness in the Z direction relative to the overall size in the XY directions is mainly used.

The laminated body S has a solidification layer 4 in addition to the workpieces 1, the supporting body 2, and the separating layer 3.

The solidification layer 4 is formed in lamination by coating of a fluid along at least the separating layer 3. At the time of lamination by coating of the solidification layer 4, or the like, the material of the solidification layer 4 may enter voids 3v of the separating layer 3 described later, to be partially bonded with the surface 2a of the supporting body 2. In other words, in the solidification layer 4, an adhesion region 4a with the surface 2a of the supporting body 2 may be generated.

Specific examples of the solidification layer 4 may include a sealing layer 4b shown in FIGS. 1 to 3, and an adhesion layer 4c shown in FIGS. 4 and 5.

For a first laminated body S1 shown in FIGS. 1 to 3 as one example of the laminated body S, a sealing layer 4b is formed in lamination along the separating layer 3 and the workpieces 1 in order to protect the workpieces 1. The sealing layer 4b is configured such that a liquid sealing material including, for example, an epoxy resin is coated so as to cover the separating layer 3 and the workpieces 1, and protects the workpieces 1 airtightly by hardening of the sealing material due to heating and sintering, or the like.

For a second laminated body S2 shown in FIGS. 4 and 5 as another example of the laminated body S, an adhesion layer 4c as an auxiliary material of the separating layer 3 is formed in lamination along the separating layer 3. The adhesion layer 4c is configured such that a liquid adhesive is coated so as to cover the separating layer 3, thereby reinforcing the adhesive property with the workpieces 1 by hardening due to heating and sintering, or the like.

Incidentally, when a light L described later is irradiated toward the separating layer 3 through the workpiece 1 side, as the sealing material of the sealing layer 4b or the adhesive of the adhesion layer 4c, it is also possible to use the one including a transparent or translucent material capable of transmitting the light L therethrough.

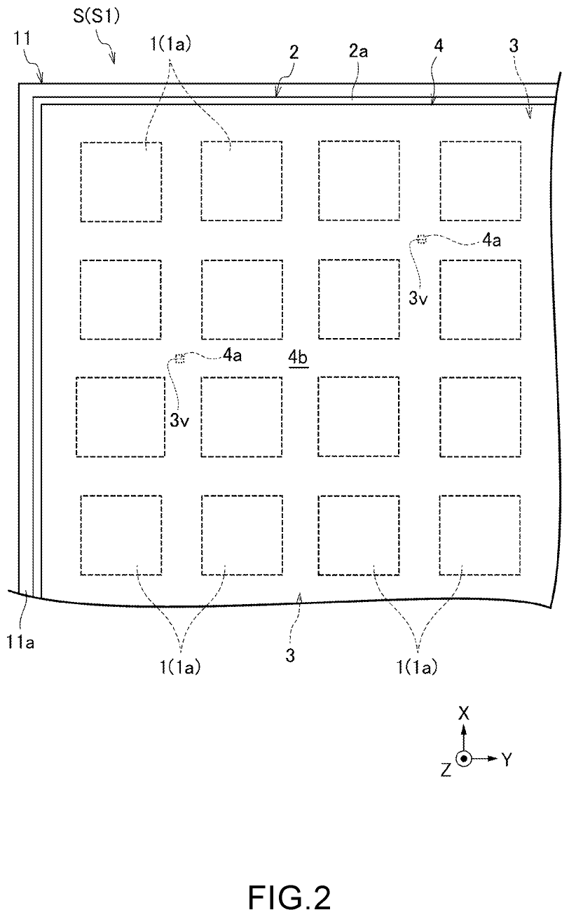

In the case of the example shown as the laminated body S, the first laminated body S1 and the second laminated body S2 are both formed in a panel shape (a rectangular shape). As shown in FIG. 2, a plurality of rectangular and very thin semiconductor elements 1a as the workpieces 1 are mounted in a parallel form at prescribed intervals (regular intervals) in the XY directions. In order to protect the plurality of semiconductor elements 1a, mold forming is achieved with the sealing layer 4b. Such first laminated body S1 and second laminated body S2 are finally cut in the XY directions by dicing or the like. Then, by going through the final process of mounting an electrode lead-out part via a rewiring layer, or other procedures. As a result, a plurality of electronic components of the final products are manufactured.

In the example shown, as the light L from a light irradiation part 22 described later, a laser light beam is transmitted through the transparent or translucent supporting body 2, and is irradiated to the separating layer 3. Accordingly, the absorption of the laser light beam changes the properties of the separating layer 3 to a peelable state.

Alternatively, although not shown as other examples of the laminated body S, changes into other structures than the example shown are also possible, such as a change in size or number of the workpieces 1 arranged, a change in thickness of the supporting body 2, the separating layer 3, the sealing layers 4b and 4b′, the adhesion layer 4c, or the like, and a change of properties of the separating layer 3 to a peelable state by irradiation with a heat ray (infrared ray) or other light beams in place of the laser light beam as the light L from the light irradiation part 22.

A molding device 10 is a molding machine for bonding the workpieces 1 and the supporting body 2 in such a manner that the separating layer 3 or the like is sandwiched therebetween.

The molding device 10 includes, as a specific example thereof, in the case shown in FIG. 1 at (a) to (c) and FIG. 4 at (a) to (c): a bonding holding member 11 provided so as to detachably hold the supporting body 2; a coating machine 12 for stacking the denature material 3m of the separating layer 3, and the like with respect to the surface 2a of the supporting body 2 held by the bonding holding member 11; a mounting machine 13 for supplying and assembling the workpieces 1 toward the separating layer 3, or the like; and a pressing machine 14 for pressurizing and bonding the workpieces 1, the separating layer 3, or the like toward the surface 2a of the supporting body 2. as main constituent elements.

Further, the molding device 10 includes a bonding controlling part 15 for operation controlling the bonding holding member 11, the coating machine 12, the mounting machine 13, the pressing machine 14, and the like.

The bonding holding member 11 is formed of a rectangular or circular surface plate, or the like which is a rigid body of a metal or the like, has a thickness not allowing distortion deformation, and has larger outer dimensions than the outer dimensions of the laminated body S (the first laminated body S1 or the second laminated body S2).

For the bonding holding member 11, a bonding holding chuck (not shown) for detachably holding the supporting body 2 is provided at the flat bonding support surface 11a opposed to the supporting body 2 in the thickness direction (Z direction).

The coating machine 12 is formed of a slot die coater, a spin coater, or the like for coating the denature material 3m of the separating layer 3, or the like on the surface 2a of the supporting body 2 with a prescribed thickness.

The mounting machine 13 is formed of a chip mounter or the like for transporting the workpieces 1 from a workpiece supply source (not shown), and assembling them at a prescribed positions of the separating layer 3, or the like.

The pressing machine 14 has a pressing plate 14a as large as or larger than the supporting body 2, and a pressurizing driving part 14b including an actuator for pushing the pressing plate 14a toward the supporting body 2 so that the workpieces 1, the separating layer 3, and the like are sandwiched therebetween.

The bonding controlling part 15 is a controller having control circuits (not shown) electrically connected with the holding chuck of the bonding holding member 11, the coating machine 12, the mounting machine 13, the pressurizing driving part 14b of the pressing machine 14, and the like, respectively. The controller to be the bonding controlling part 15 respectively performs operation control successively at a preset timing according to the program preset in the control circuit.

Then, the program set in the control circuit of the bonding controlling part 15 will be described as the workpiece molding method of the laminated body S (the first laminated body S1 or the second laminated body S2) by the molding device 10 of the workpiece separating device A.

The molding step of the workpiece separating method using the molding device 10 in the workpiece separating device A (A1 or A2) in accordance with the embodiment (the first embodiment or the second embodiment) of the present invention includes: a holding process of detachably holding the supporting body 2 with respect to the bonding support surface 11a of the bonding holding member 11; a coating process of coating the denature material 3m of the separating layer 3, or the like along the supporting body 2 held by the bonding holding member 11; a mounting process of supplying and assembling the workpieces 1 toward the separating layer 3, or the like; and a pressing process of pressurizing and bonding the workpieces 1, the separating layer 3, and the like toward the surface 2a of the supporting body 2, as main processes.

In the case of the first laminated body S1, as the first coating process, as shown in FIG. 1 at (a), the denature material 3m of the separating layer 3 is coated with a uniform thickness by the operation of the coating machine 12 along the surface 2a of the supporting body 2 held by the bonding holding member 11.

Then, as the mounting process, as shown in FIG. 1 at (b), the semiconductor elements 1a to be the workpieces 1, or the like are assembled with respect to prescribed positions of the layer surface of the separating layer 3 by the operation of the mounting machine 13.

Thereafter, as the second coating process, as indicated with a solid line of FIG. 1 at (c), the sealing material of the sealing layer 4b is coated with a prescribed thickness along the surface 2a of the supporting body 2 and the workpieces 1 by the operation of the coating machine 12.

Finally, as the pressing process, as indicated with a two-dot chain line of FIG. 1 at (c), the pressing plate 14a comes in contact with the layer surface of the sealing layer 4b by the operation of the pressing machine 14, and pressurizes the sealing material of the sealing layer 4b toward the surface 2a of the supporting body 2. Accordingly, the workpieces 1 or the like are mold formed with respect to the supporting body 2 with the separating layer 3 interposed therebetween, resulting in the first laminated body S1 with a prescribed thickness.

In the case of the second laminated body S2, as the first coating process, as indicated with a solid line of FIG. 4 at (a), the denature material 3m of the separating layer 3 is coated with a uniform thickness along the surface 2a of the supporting body 2 held by the bonding holding member 11 by the operation of the coating machine 12.

Then, as the second coating process, as indicated with a two-dot chain line of FIG. 4 at (a), the adhesive of the adhesion layer 4c is coated with a uniform thickness along the layer surface of the separating layer 3 by the operation of the coating machine 12.

Next, as the mounting process, as shown in FIG. 4 at (b), the semiconductor elements 1a to be the workpieces 1, or the like are assembled with respect to the prescribed positions of the layer surface of the adhesion layer 4c by the operation of the mounting machine 13.

Subsequently, as the second coating process, as indicated with a solid line of FIG. 4 at (c), the sealing material of the sealing layer 4b′ is coated with a prescribed thickness along the layer surface of the adhesion layer 4c and the workpieces 1 by the operation of the coating machine 12.

Finally, as the pressing process, as indicated with a two-dot chain line of FIG. 4 at (c), by the operation of the pressing machine 14, the pressing plate 14a comes in contact with the layer surface of the sealing layer 4b′, and pressurizes the sealing material of the sealing layer 4b′ toward the surface 2a of the supporting body 2. Accordingly, the workpieces 1 or the like are mold formed with respect to the supporting body 2 with the adhesion layer 4c and the separating layer 3 interposed therebetween, resulting in the second laminated body S2 with a prescribed thickness.

A peeling device 20 is a device for causing denature (change of properties) so as to reduce the adhesive strength of the separating layer 3 due to irradiation with a light L, and enabling peeling between the workpieces 1 and the supporting body 2.

In particular, the peeling device 20 includes: a peeling holding member 21 provided so as to detachably hold any one of the workpiece 1 side or the supporting body 2 of the laminated body S; and a light irradiation part 22 provided so as to irradiate the separating layer 3 with a light L through the supporting body 2 or the workpiece 1 side (the sealing layer 4b or 4b′) of the laminated body S as main constituent elements.

Further, the peeling device 20 includes: a peeling isolation member 23 for isolating and moving, with respect to any one of the workpiece 1 side (the sealing layer 4b or 4b′) or the supporting body 2 of the laminated body S, the other in the thickness direction (Z direction); and a peeling controlling part 24 for operation controlling the light irradiation part 22, and the peeling isolation member 23, and the like.

Further, the peeling device 20 includes a detection part 25 for detecting the position of the adhesion regions 4a of a solidification layer 4 described later, and can also operation control the light irradiation part 22 based on a detection signal from the detection part 25.

The peeling holding member 21 is formed of a rectangular or circular surface plate, or the like which is a rigid body of a metal or the like, has a thickness not allowing distortion deformation, and has larger outer dimensions than the outer dimensions of the laminated body S (the first laminated body S1 or the second laminated body S2).

For the peeling holding member 21, a peeling holding chuck (not shown) for detachably holding any one of the workpiece 1 side (the sealing layer 4b or 4b′) or the supporting body 2 of the laminated body S (the first laminated body S1 or the second laminated body S2) bonded and formed by the molding device 10 is provided at the flat peeling holding surface 21a opposed to the laminated body S (the first laminated body S1 or the second laminated body S2) in the thickness direction (Z direction).

The light irradiation part 22 is provided as a part of an optical system (not shown) for guiding a light L from a light source (not shown) such as a laser oscillator in the thickness direction (Z direction) with respect to the laminated body S (the first laminated body S1 or the second laminated body S2).

The light irradiation part 22 has a laser scanner 22a for moving the optical axis (main axis) of the laser light beam as the light L, and a lens 22b for condensing the laser light beam in the case of the example shown as a specific example of the light irradiation part 22. The laser scanner 22a scans (sweeps) the laser light beam irradiated toward the separating layer 3 of the first laminated body S1 or the second laminated body S2 via the lens 22b in two directions (XY directions) crossing with the light irradiation direction (Z direction).

Further, when the overall size of the laminated body S (the first laminated body S1 or the second laminated body S2) is large, any one of the peeling holding member 21 or the laser scanner 22a, or both of the peeling holding member 21 and the laser scanner 22a can also be relatively moved in the two directions (XY directions) crossing with the light irradiation direction (Z direction).

In particular, the region of the laser light beam to be irradiated from the laser scanner 22a toward the laminated body S (the first laminated body S1 or the second laminated body S2) held by the peeling holding member 21 is preferably subjected to aligned irradiation with a spot-shaped laser light beam from the laser scanner 22a on a per irradiation region basis (unit irradiation region by unit irradiation region) with respect to a plurality of irradiation regions obtained by dividing the whole irradiation surface of the separating layer 3 into the plurality of irradiation regions in the two directions (XY directions).

Alternatively, although not shown as another example of the light irradiation part 22, it is also possible to achieve a change so that irradiation with a heat ray (infrared ray) other than the laser light beam or other light beams causes a change in properties of the separating layer 3 to a peelable state in place of the laser scanner 22a and the lens 22b.

A peeling isolation member 23 is a relatively moving mechanism for relatively separating, with respect to any one of the workpiece 1 side (the sealing layer 4b or 4b′) or the supporting body 2 of the laminated body S (the first laminate body S1 or the second laminated body S2) held by the peeling holding member 21, the other thereof in the thickness direction (Z direction).

The peeling isolation member 23 has, in the case of the example shown as the specific example of the peeling isolation member 23, a suction pad 23a for sucking the back surface 2b of the supporting body 2 of the laminated body S (the first laminated body S1 or the second laminated body S2) held by the peeling holding member 21, and a peeling driving part 23b including an actuator, and the like for separating the suction pad 23a from the workpiece 1 side (the sealing layer 4b or 4b′) in the Z direction.

Further, although not shown as another example of the peeling isolation member 23, it is also possible to achieve a change into other structures than the example shown.

Further, if required, there can also be included a load detection means (not shown) for detecting the load acting on the workpiece 1 side (the sealing layer 4b or 4b′) during the isolating movement, with respect to any one of the workpiece 1 side (the sealing layer 4b or 4b′) or the supporting body 2 of the laminated body S (the first laminated body S1 or the second laminated body S2), of the other.

Incidentally, when the denature material 3m of the separating layer 3 is stacked along the surface 2a of the supporting body 2, coating is required to be performed so that air bubbles are not generated in the denature material 3m.

However, when the overall size of the laminated body S (the first laminated body S1 or the second laminated body S2) is large such as a side of 500 mm or more in the case of a rectangular shape, or a diameter of 200 mm, or 300 mm or more in the case of a circular shape, it becomes difficult to use a spin coating method as the lamination method of the separating layer 3. Accordingly, the method is limited to a slit coating method, and the like. When the denature material 3m is coated with a slit coating method, or the like, air bubbles become more likely to be mixed in the denature material 3m during coating as compared with the spin coating method.

The air bubbles mixed in the denature material 3m coated along the surface 2a of the supporting body 2 become voids (cavities) 3v and are left in the separating layer 3 even after performing heating and sintering, and the like. When the material of the solidification layer 4 (the sealing material of the sealing layer 4b or the adhesive of the adhesion layer 4c) is coated in this state, the material of the solidification layer 4 (the sealing material of the sealing layer 4b or the adhesive of the adhesion layer 4c) may flow into the voids 3v, and may come in partial contact with the surface 2a of the supporting body 2. The material of the solidification layer 4 (the sealing material of the sealing layer 4b or the adhesion layer 4c) which has come in contact with the surface 2a of the supporting body 2 is solidified, resulting in partial adhesion regions 4a.

In such a state in which the adhesion regions 4a of the solidification layer 4 partially adheres to the surface 2a of the supporting body 2, even when the denature material 3m is denatured (changed in properties) to a peelable state with irradiation with a light L over the entire surface of the separating layer 3 from the light irradiation part 22, the adhesion regions 4a to the surface 2a of the supporting body 2 are partially left. For this reason, it becomes impossible to smoothly separate the supporting body 2 from the workpieces 1 and the solidification layer 4.

As a result of this, when the supporting body 2 was forcedly peeled, it was probable that damages were inflicted such as generation of cracks in the workpieces 1 or the solidification layer 4 from the adhesion regions 4a.

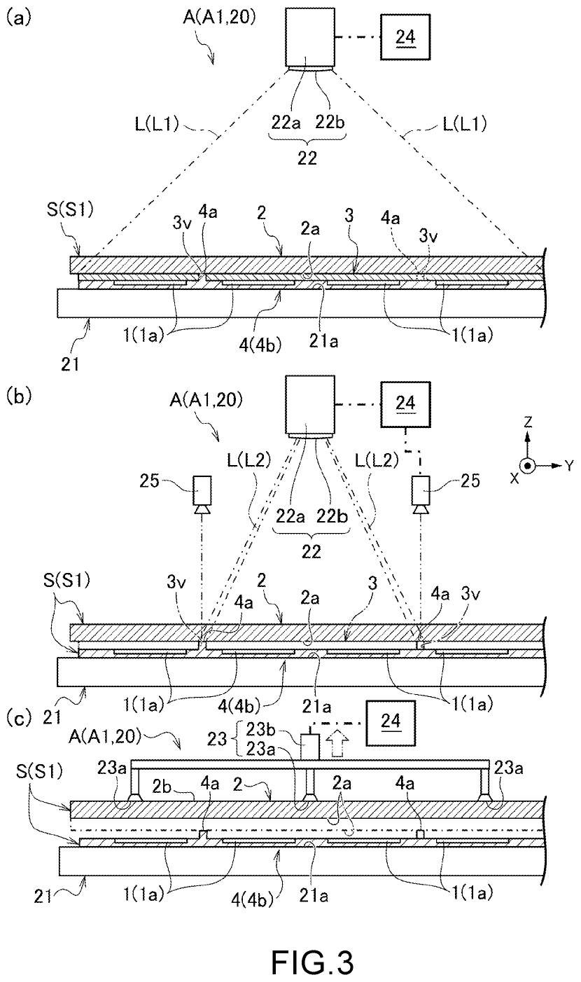

Under such circumstances, in order to solve such a problem, as shown in FIG. 3 at (a) to (c) and FIG. 5 at (a) to (c), a workpiece separating device A in accordance with an embodiment of the present invention partially irradiates only the adhesion regions 4a of the solidification layer 4 with a light L from the light irradiation part 22 again, and thereby effects a light reaction so as to enable the adhesion regions 4a to be peeled from the surface 2a of the supporting body 2.

Namely, a peeling controlling part 24 described later performs control so as to perform whole irradiation L1 in which the entire surface of the separating layer 3 is irradiated with a light L such as a laser light beam, a heat ray (infrared ray), or other light beams from the light irradiation part 22, and selective irradiation L2 in which only the adhesion regions 4a between the surface 2a of the supporting body 2 and the solidification layer 4 is partially irradiated with a light L.

For a workpiece separating device A1 in accordance with a first embodiment of the present invention, as shown in FIG. 3 at (a) to (c), the adhesion regions 4a including the sealing material of the sealing layer 4b which has flowed into the voids 3v of the separating layer 3 when the sealing layer 4b is stacked along the separating layer 3 and the workpieces 1 of the first laminated body S1 is subjected to selective irradiation L2 with a light (laser light beam) L from the light irradiation part 22 (laser scanner 22a).

Further, for a workpiece separating device A2 in accordance with a second embodiment of the present invention, as shown in FIG. 5 at (a) to (c), the adhesion regions 4a including the adhesive of the adhesion layer 4c which has flowed into the voids 3v of the separating layer 3 when the adhesion layer 4c is stacked along the separating layer 3 of the second laminated body S2 is subjected to selective irradiation L2 with a light (laser light beam) L from the light irradiation part 22 (laser scanner 22a).

On the other hand, the material of the solidification layer 4 (the sealing material of the sealing layer 4b or the adhesive of the adhesion layer 4c) flows into the voids 3v, and comes in contact with the surface 2a of the supporting body 2, resulting in adhesion regions 4a. Only the adhesion regions 4a are discolored from other surrounding sites due to the first whole irradiation L1.

This enables the position detection of the discolored adhesion regions 4a with a detection part 25.

As the detection part 25, an optical machine including a test camera, or the like is used. Preferably, the positions of the discolored adhesion regions 4a are detected by observation of the adhesion regions 4a through the supporting body 2 or the workpiece 1 side (sealing layer 4b or 4b′).

When a specific example of the detection part 25 is indicated with a two-dot chain line of FIG. 3 at (b) or a two-dot chain line of FIG. 5 at (b), at the time point before the selective irradiation L2 only to the adhesion regions 4a by the light irradiation part 22, with an optical machine as the detection part 25, the coordinates of the adhesion regions 4a are detected through the transparent or translucent supporting body 2, and the coordinate signal is sent to a peeling controlling part 24 described later.

Further, although not shown as another example of the detection part 25, the following changes are possible: the position detection by interference fringe is adopted in place of the position detection of the discolored adhesion regions 4a; the coordinates of the adhesion regions 4a are detected by visual observation by an operator, and the coordinate data is directly inputted to a peeling controlling part 24 described layer; and other changes.

In addition to this, the adhesion regions 4a including the material of the solidification layer 4 (the sealing material of the sealing layer 4b or the adhesive of the adhesion layer 4c) are dissimilar to the denature material 3m of the separating layer 3. For this reason, even when the light (laser light beam) L is irradiated thereto as with the denature material 3m of the separating layer 3, it is probable that the adhesion region 4a does not reach the decomposition threshold value, and that the denature reaction allowing peeling is not effected.

In such a case, as the selective irradiation L2, any one of, or any combination of, “higher power partial irradiation” or “more overlapping partial irradiation”, or “higher density partial irradiation” as compared with the irradiation with the light (laser light beam) L with respect to the separating layer 3 is preferably carried out.

In other words, in accordance with the decomposition threshold value of the material of the solidification layer 4 (the sealing material of the sealing layer 4b or the adhesive of the adhesion layer 4c), partial irradiation is performed with a high power from the light irradiation part 22, partial irradiation to the adhesion regions 4a is repeated a large number of times, or the pulse pitch (interval) of the light (laser light beam) L to the adhesion regions 4a is narrowed, thereby performing partial irradiation. As a result, the decomposition threshold value is exceeded.

The peeling controlling part 24 is a controller having a control circuit (not shown) electrically connected respectively with a bonding controlling part 15 of the molding device 10, and the like in addition to the holding chuck of the peeling holding member 21, the light irradiation part 22 (laser scanner 22a), and the peeling driving part 23b of the peeling isolation member 23. The controller serving as the peeling controlling part 24 successively performs operation controls at respective preset timings according to a program preset at the control circuit.

Then, the program set at the control circuit of the peeling controlling part 24 will be described as the workpiece separating method by a peeling device 20 of the workpiece separating device A.

The separating step of the workpiece separating method using the peeling device 20 in the workpiece separating device A (A1 or A2) in accordance with the embodiment (the first embodiment or the second embodiment) of the present invention, includes a holding process of detachably holding any one of the workpiece 1 side or the supporting body 2 of the laminated body S at the peeling holding member 21, a light irradiation process of irradiating a light L from the light irradiation part 22 toward the separating layer 3 through the other of the supporting body 2 or the workpiece 1 side of the laminated body S held by the peeling holding member 21, and an isolating process of isolating and moving, with respect to any one of the workpiece 1 side or the supporting body 2 of the laminated body S, the other in the thickness direction as main processes.

Further, the separating step preferably includes a position detecting process of position detecting the adhesion regions 4a of the solidification layer 4 by the detection part 25, and operation controlling the light irradiation part 22 based on a detection signal from the detection part 25.

At the holding process, by the operation of a transport mechanism (not shown) such as a transport robot, the laminated body S (the first laminated body S1 or the second laminated body S2) is transported toward the peeling holding member 21. Any one of the workpiece 1 side or the supporting body 2 of the laminated body S (the first laminated body S1 or the second laminated body S2) bonded and molded by the molding device 10 is held at a prescribed position in the peeling holding surface 21a of the peeling holding member 21 unmovably by a holding chuck.

In the case of the first laminated body S1 shown in FIG. 3 at (a), the first laminated body S1 bonded and molded by the molding device 10 is vertically inverted, and the sealing layer 4b on the workpiece 1 side is held at the peeling holding surface 21a of the peeling holding member 21. Accordingly, the supporting body 2 is arranged so as to be opposed to the light irradiation part 22 (laser scanner 22a) in the Z direction.

In the case of the second laminated body S2 shown in FIG. 5 at (a), the second laminated body S2 bonded and molded by the molding device 10 is vertically inverted, and the sealing layer 4b′ on the workpiece 1 side is held at the peeling holding surface 21a of the peeling holding member 21. Accordingly, the supporting body 2 is arranged so as to face the light irradiation part 22 (laser scanner 22a) in the Z direction.

At the light irradiation process, toward the laminated body S (the first laminated body S1 or the second laminated body S2) held by the peeling holding member 21, a light (laser light beam) L is irradiated to the separating layer 3 through the supporting body 2 or the workpiece 1 side by the operation of the optical system and the light irradiation part 22 (laser scanner 22a).

For light irradiation to the separating layer 3, first, whole irradiation L1 in which a light (laser light beam) L is irradiated over the entire surface of the separating layer 3, and selective irradiation L2 in which a light (laser light beam) L is irradiated partially to only the adhesion regions 4a between the surface 2a of the supporting body 2 and the solidification layer 4 are performed.

In the case of the first laminated body S1 shown in FIG. 3 at (a), the whole irradiation L1 over the entire surface of the separating layer 3 of the first laminated body S1 is performed. Then, the selective irradiation L2 is performed on only the adhesion regions 4a including the sealing material of the sealing layer 4b which has flown into the voids 3v of the separating layer 3 as shown in FIG. 3 at (b).

In the case of the second laminated body S2 shown in FIG. 5 at (a), the whole irradiation L1 is performed over the entire surface of the separating layer 3 of the second laminated body S2. Then, the selective irradiation L2 is performed on only the adhesion regions 4a including the adhesive of the adhesion layer 4c which has flown into the voids 3v of the separating layer 3 as shown in FIG. 5 at (b).

Further, in such a selective irradiation process with respect to the adhesion regions 4a, as indicated with two-dot chain lines of FIG. 3 at (b) or two-dot chain lines of FIG. 5 at (b), a position detecting process of position detecting the adhesion regions 4a of the solidification layer 4 by the detection part 25, and operation controlling the light irradiation part 22 based on a detection signal from the detection part 25 is preferably carried out. This enables the selective irradiation L2 to be performed with precision with respect to only the adhesion regions 4a.

Further, in the selective irradiation process with respect to the adhesion regions 4a, it is preferable to carry out any one of, or any combination of, “higher power partial irradiation” or “more overlapping partial irradiation to only the adhesion regions 4a”, or “higher density partial irradiation” than the whole irradiation L1 with respect to the separating layer 3.

In the isolating process, the operation of the peeling isolation member 23 isolates and moves away, with respect to any one of the workpiece 1 side (the sealing layer 4b or 4b′) or the supporting body 2 of the laminated body S (the first laminated body S1 or the second laminated body S2) held by the peeling holding member 21, the other in the thickness direction (Z direction).

In the case of the first laminated body S1 shown in FIG. 3 at (c), the supporting body 2 is isolated and moved away in the Z direction from the workpieces 1 and the sealing layer 4b of the first laminated body S1 held by the peeling holding member 21.

In the case of the second laminated body S2 shown in FIG. 5 at (c), the supporting body 2 is isolated and moved away in the Z direction from the workpieces 1, the sealing layer 4b′, and the adhesion layer 4c of the second laminated body S2 held by the peeling holding member 21.

Further, when the load acting on the workpiece 1 side (the sealing layer 4b or 4b′) becomes equal to, or larger than a set value by the load detecting means during isolation and movement of, with respect to any one of the workpiece 1 side (the sealing layer 4b or 4b′) or the supporting body 2 of the laminated body S (the first laminated body S1 or the second laminated body S2), of the other, it is also possible to stop the operation of the peeling isolation member 23. As a result of this, it becomes possible to perform reexecution of the position detecting process or the operator's visual observation operation at the time point when damage is not inflicted on the workpiece 1 side (the sealing layer 4b or 4b′).

With the workpiece separating device A and the workpiece separating method in accordance with such an embodiment of the present invention, the material of the solidification layer 4 may flow into the voids 3v generated in a part of the separating layer 3 stacked along the surface 2a of the supporting body 2, to be solidified, which may result in the formation of the adhesion regions 4a with the surface 2a of the supporting body 2.

In this case, the whole irradiation L1 is performed over the entire surface of the separating layer 3 with a light L from the light irradiation part 22. Accordingly, the whole of the separating layer 3 is denatured (changed in properties) to a peelable state, and the selective irradiation L2 in which only the adhesion regions 4a are partially irradiated with the light L is performed.

This effects the light reaction of the adhesion regions 4a of the solidification layer 4, which enables peeling from the surface 2a of the supporting body 2.

Therefore, the partial adhesion regions 4a between the supporting body 2 and the solidification layer 4 is selectively irradiated with a light L. As a result, the supporting body 2 can be peeled from the solidification layer 4 with ease.

As a result, as compared with a conventional one in which, when voids are formed in the separating layer stacked along the supporting body, the thermosetting resin which has flown into the voids is partially rendered in an adhesion state, the following will not be caused: forced separation causing a damage on a device formed at a circuit mounted on a semiconductor substrate, causing cracks in the workpieces 1 and the solidification layer 4, and breaking the workpieces 1 and the solidification layer 4.

For this reason, the high-precision separation of the supporting body 2 from the workpieces 1 can be implemented, so that a high-performance and clean product can be manufactured. As a result of this, the yield and the processability can be improved.

In particular, the solidification layer 4 is preferably the sealing layer 4b. In this case, as shown in FIG. 3 at (a) to (c), the selective irradiation L2 with the light L from the light irradiation part 22 with respect to the adhesion regions 4a including the sealing material of the sealing layer 4b which has flowed into the voids 3v of the separating layer 3 effects the light reaction of the adhesion regions 4a including the sealing material of the sealing layer 4b. This enables peeling from the surface 2a of the supporting body 2.

Therefore, the partial adhesion regions 4a including the sealing material of the sealing layer 4b with the supporting body 2 is selectively irradiated with a light L. As a result, the supporting body 2 can be peeled from the sealing layer 4b with ease.

As a result, it is possible to prevent cracking or breakage of the workpieces 1 and the sealing layer 4b accompanying peeling of the supporting body 2 from the workpieces 1.

Further, the solidification layer 4 is preferably the adhesion layer 4c.

In this case, as shown in FIG. 5 at (a) to (c), the selective irradiation L2 with the light L from the light irradiation part 22 with respect to the adhesion regions 4a including the adhesive of the adhesion layer 4c which has flowed into the voids 3v of the separating layer 3 effects the light reaction of the adhesion regions 4a including the adhesive of the adhesion layer 4c. This enables peeling from the surface 2a of the supporting body 2.

Therefore, the partial adhesion regions 4a including the adhesive of the adhesion layer 4c with the supporting body 2 is selectively irradiated with the light L. As a result, the supporting body 2 can be peeled from the adhesion layer 4c with ease.

As a result, it is possible to prevent breakage of the workpieces 1 and the adhesion layer 4c accompanying peeling of the supporting body 2 from the workpieces 1.

Further, preferably, a detection part 25 for position detecting the adhesion regions 4a of the solidification layer 4 is included, and the light irradiation part 22 is operation controlled based on a detection signal from the detection part 25.

In this case, at the detection part 25, the adhesion regions 4a of the solidification layer 4 are position detected, and the light irradiation part 22 is operation controlled based on a detection signal from the detection part 25. As a result, only the adhesion regions 4a are partially irradiated with a light L from the light irradiation part 22.

Therefore, selective irradiation L2 is performed with the light L with precision with respect to only the partial adhesion regions 4a between the supporting body 2 and the solidification layer 4. This enables the supporting body 2 to be peeled from the solidification layer 4 with reliability.

As a result, it is possible to prevent the false irradiation with the light L with respect to the periphery of the adhesion regions 4a, and the high-precision separation of the supporting body 2 from the workpieces 1 becomes feasible. Thus, a still higher-performance and clean product can be manufactured. As a result of this, the yield and the processability can be further improved.

Further, the selective irradiation L2 from the light irradiation part 22 with respect to the adhesion regions 4a of the solidification layer 4 preferably includes any one of, or any combination of, higher power partial irradiation or more overlapping partial irradiation to only the adhesion regions 4a, or higher density partial irradiation than the whole irradiation L1 with respect to the separating layer 3.

In this case, in accordance with the decomposition threshold value of the material of the solidification layer 4, partial irradiation is performed with a high power from the light irradiation part 22, partial irradiation with respect to the adhesion regions 4a is repeated a large number of times, and the pulse pitch (interval) of the light (laser light beam) L with respect to the adhesion regions 4a is narrowed, thereby performing partial irradiation.

As a result of this, it becomes possible that the decomposition threshold value of the material of the solidification layer 4 can be exceeded.

Therefore, even when the adhesion regions 4a of the solidification layer 4 are dissimilar to the material (the denature material 3m) of the separating layer 3, they are decomposed with reliability, and can be allowed to undergo a light reaction to a peelable state.

As a result, high-precision separation of the supporting body 2 from the workpieces 1 becomes feasible, so that a still higher-performance and clean product can be manufactured.

Incidentally, in the examples shown in the embodiments (the first embodiment and the second embodiment), the first laminated body S1 and the second laminated body S2 were both formed in a panel shape (rectangular shape). However, not limited thereto, the first laminated body S1 and the second laminated body S2 may be both formed in a wafer shape (circular shape).

Further, the arrangement was achieved such that the light (laser light beam) L from the light irradiation part 22 (laser scanner 22a) is transmitted through the supporting body 2, to be irradiated to the separating layer 3. However, not limited thereto, the light L may be transmitted from the workpiece 1 side, to be irradiated to the separating layer 3.

Also in this case, the same actions and advantages as those of the first embodiment and the second embodiment can be obtained.

### REFERENCE SIGNS LIST

A Workpiece separating device
1 Workpiece
2 Supporting body
2a Front surface
3 Separating layer
4 Solidification layer
4a Adhesion region
4b Sealing layer
4c Adhesion layer
21 Holding member (Peeling holding member)
22 Light irradiation part
23 Isolation member (Peeling isolation member)
24 Controlling part (Peeling controlling part)
25 Detection part
L Light
L1 Whole irradiation
L2 Selective irradiation
S Laminated body

1. A workpiece separating device for irradiating a laminated body including a workpiece having a circuit substrate bonded with a supporting body via a separating layer with a light, thereby denaturing the separating layer, and peeling the supporting body from the workpiece, the workpiece separating device comprising:
a holding member for detachably holding any one of the workpiece side or the supporting body of the laminated body;
a light irradiation part for irradiating the light toward the separating layer through the other of the supporting body or the workpiece side of the laminated body held by the holding member;
an isolation member for, with respect to any one of the workpiece side or the supporting body of the laminated body, isolating and moving the other in the thickness direction; and
a controlling part for operation controlling the light irradiation part and the isolation member, wherein
the laminated body has the separating layer stacked along a surface of the supporting body, and a solidification layer stacked along the separating layer; and
the controlling part performs control such that whole irradiation in which the light is irradiated over the entire surface of the separating layer by the light irradiation part and selective irradiation in which the light is partially irradiated to only an adhesion region between the surface of the supporting body and the solidification layer are performed.

2. The workpiece separating device according to claim 1, wherein the solidification layer is a sealing layer.

3. The workpiece separating device according to claim 1, wherein the solidification layer is an adhesion layer.

4. The workpiece separating device according to claim 1, further comprising a detection part for position detecting the adhesion region of the solidification layer, wherein the light irradiation part is operation controlled based on a detection signal from the detection part.

5. The workpiece separating device according to claim 1, wherein the selective irradiation from the light irradiation part with respect to the adhesion region of the solidification layer includes any one of, or any combination of, higher power partial irradiation, or more overlapping partial irradiation to only the adhesion region, or higher density partial irradiation than the whole irradiation with respect to the separating layer.

6. A workpiece separating method for, with respect to a laminated body including a workpiece having a circuit substrate stacked with a supporting body via a separating layer, peeling the supporting body from the workpiece due to denaturing of the separating layer accompanying irradiation with a light, the method comprising:
a holding process of detachably holding any one of the workpiece side or the supporting body of the laminated body at a holding member; and
a light irradiation process of irradiating the light from the light irradiation part toward the separating layer through the other of the supporting body or the workpiece side of the laminated body held by the holding member, wherein
the laminated body has the separating layer stacked along a surface of the supporting body and a solidification layer stacked along the separating layer; and
at the light irradiation process, whole irradiation in which the light is irradiated over the entire surface of the separating layer by the light irradiation part and selective irradiation in which the light is partially irradiated only to an adhesion region between the surface of the supporting body and the solidification layer are performed.

7. The workpiece separating device according to claim 2, further comprising a detection part for position detecting the adhesion region of the solidification layer, wherein the light irradiation part is operation controlled based on a detection signal from the detection part.

8. The workpiece separating device according to claim 3, further comprising a detection part for position detecting the adhesion region of the solidification layer, wherein the light irradiation part is operation controlled based on a detection signal from the detection part.

9. The workpiece separating device according to claim 2, wherein the selective irradiation from the light irradiation part with respect to the adhesion region of the solidification layer includes any one of, or any combination of, higher power partial irradiation, or more overlapping partial irradiation to only the adhesion region, or higher density partial irradiation than the whole irradiation with respect to the separating layer.

10. The workpiece separating device according to claim 3, wherein the selective irradiation from the light irradiation part with respect to the adhesion region of the solidification layer includes any one of, or any combination of, higher power partial irradiation, or more overlapping partial irradiation to only the adhesion region, or higher density partial irradiation than the whole irradiation with respect to the separating layer.

11. The workpiece separating device according to claim 4, wherein the selective irradiation from the light irradiation part with respect to the adhesion region of the solidification layer includes any one of, or any combination of, higher power partial irradiation, or more overlapping partial irradiation to only the adhesion region, or higher density partial irradiation than the whole irradiation with respect to the separating layer.

12. The workpiece separating device according to claim 7, wherein the selective irradiation from the light irradiation part with respect to the adhesion region of the solidification layer includes any one of, or any combination of, higher power partial irradiation, or more overlapping partial irradiation to only the adhesion region, or higher density partial irradiation than the whole irradiation with respect to the separating layer.

13. The workpiece separating device according to claim 8, wherein the selective irradiation from the light irradiation part with respect to the adhesion region of the solidification layer includes any one of, or any combination of, higher power partial irradiation, or more overlapping partial irradiation to only the adhesion region, or higher density partial irradiation than the whole irradiation with respect to the separating layer.
